(19) United States
(12) Patent Application Publication
(10) Pub. No.: US 2001/0052573 A1
(43) Pub. Date: Dec. 20, 2001

(54) Target mark member, method for manufacturing, and electron beam exposure apparatus thereof

(75) Inventor: Masaki Takakuwa, Tokyo (JP)

Correspondence Address: PILLSBURY WINTHROP LLP, 1600 TYSONS BOULEVARD, MCLEAN, VA, 22102, US

(73) Assignee: ADVANTEST CORPORATION

(21) Appl. No.: 09/879,992

(22) Filed: Jun. 14, 2001

(30) Foreign Application Priority Data
Jun. 19, 2000 (JP) 2000-182788

(51) Int. Cl. G03F 7/207; B32B 3/10; G03F 9/00; H01J 3/02; H01J 3/22; H01J 3/32; B32B 15/04; C23C 14/16; C23C 14/34; C30B 23/02

(52) U.S. Cl. 250/398; 428/614; 428/635; 428/641; 428/665; 250/492.2; 430/5; 430/296; 204/192.15; 117/108

(57) ABSTRACT

A target mark member having a mark pattern with a plurality of marks and a controlled width of the marks provides accuracy and efficiency in electron beam shape measurement and focus of the electron beam. The target mark member for adjusting a focus of an electron beam and measuring a shape of said electron beam in an electron beam processing apparatus includes a metal mark portion having a predetermined mark pattern, said metal mark portion comprising an epitaxial metal material; and a substrate that supports said metal mark portion.

This patent application claims priority from a Japanese patent application No. 2000-182788 filed on Jun. 19, 2000, the contents of which are incorporated herein by reference.

### BACKGROUND OF THE INVENTION

1. Field of the Invention

The present invention relates to a target mark member, which is used for adjusting a focus of an electron beam or measuring the beam shape of an electron beam of an electron beam processing apparatus such as an electron beam exposure apparatus. More particularly, the present invention relates to a target mark member that comprises a metal mark portion, which is epitaxially grown, having a micro line width.

2. Description of the Related Art

During exposing a pattern on a sample or wafer using an electron beam exposure apparatus, it is necessary to adjust the shape of an electric current distribution of an electron beam on a surface of the wafer to a desired shape. In the following, the shape of an electric current distribution of an electron beam on a surface of the wafer will be called as an electron beam shape. Therefore, it is important to find previously the shape of the beam formed by an electron lens before the exposure process. It is also important to adjust the focus of the electron beam exposure apparatus so that the electron beam can form an image on a sample.

FIG. 1 shows an operation of measuring a shape of an electron beam and focusing an electron beam using a conventional target mark member 170. The target mark member 170 has a metal mark portion 162 formed by a heavy metal and a substrate 164 formed by a material such as silicon. Processing a heavy metal membrane, which is vacuum-evaporated on the substrate 164 by sputtering, using lithography, forms the metal mark portion 162. The metal mark portion 162 of the conventional target mark member 170 is formed to have a line width of X0-X1.

As one of the methods of measuring the electron beam shape, there is a method of obtaining a two-dimensional distribution of the electron beam, which corresponds to a position of deflection, by scanning the metal mark portion 162 in two dimension using an electron beam and recording the electron signal, which is reflected from the metal mark portion 162, while synchronizing the reflected electron signal with the beam scanning signal of the deflection circuit. Furthermore, in case of focusing the electron beam, the target mark member 170 is scanned by the electron beam, and the amount of an electron, which is reflected from the target mark member 170, is detected by an electron detector that is provided in the electron beam processing apparatus. The focus of the electron beam is adjusted by measuring the degree of focus of the electron beam based on this change of the amount of the reflected electrons.

FIG. 2 shows an example of the measuring result of the amount of the reflected electrons, the focus of which is adjusted using the conventional target member 170. FIG. 2A shows a profile of a measured amount of the reflected electrons. The amount of scattered electrons shows approximately a maximum value at the periphery of the edge (X0, X1) of the metal mark portion 162.

FIG. 2B shows a result that differentiates the profile of the measured amount of scattered electrons of FIG. 2A. The inclination of the curve of FIG. 2A shows the maximum and the minimum value at the periphery of the edge (X0, X1) of the metal mark portion 162. The difference of the maximum value and the minimum value of the inclination is shown as P in FIG. 2B. If P increases, it is judged that the electron beam is focused. Contrary, if P decreases, it is judged that the electron beam is not focused. The target mark member 170 is scanned by the electron beam for a plurality of times, and the control system of the electron beam processing apparatus sets the condition of the electron optical system by obtaining the average value of the plurality of values of P.

Because the conventional metal mark portion 162 is formed by the lithography process, it is difficult to reduce the line width from X0 to X1 narrower than the minimum processing size of the lithography process. Therefore, the measuring accuracy of the electron beam shape is limited to the line width of the metal mark portion 162. Therefore, it is difficult to measure the beam shape, the line width of which is narrower than the line width of the metal mark portion 162. Moreover, because the metal mark portion 162 is vapor deposited on the substrate 164 by sputtering the metal material on the substrate 164, the crystallinity of the metal mark portion 162 is unsuitable. Thus, an electron trap level is formed in the metal mark portion 162 so that the sheet resistance of the metal mark portion 162 cannot be reduced. It is not a desirable condition for the irradiation of the electron beam if the sheet resistance of the metal mark portion 162 is large.

Moreover, as explained in FIG. 2, because the line width of the metal mark portion 162 is thick, the target mark member 170 has to be scanned by the electron beam a plurality of times to measure the degree of focus of the electron beam. Therefore, there is a problem in the time that is taken for adjusting a focus when using the conventional target mark member 170.

### SUMMARY OF THE INVENTION

Therefore, it is an object of the present invention to provide a target mark member, method for manufacturing a target mark member, and an electron beam exposure apparatus that incorporate a target mark member, which is capable of overcoming the above drawbacks accompanying the conventional art. The above and other objects can be achieved by combinations described in the independent claims. The dependent claims define further advantageous and exemplary combinations of the present invention.

According to a first aspect of the present invention, a target mark member for adjusting a focus of an electron beam and measuring a shape of said electron beam in an electron beam processing apparatus is provided. The target mark member comprises a metal mark portion having a predetermined mark pattern, said metal mark portion comprising an epitaxial metal material; and a substrate that supports the metal mark portion.

The substrate may have a groove that has side walls; and the metal mark portion may have a epitaxial metal membrane on at least one of the side walls of the groove. The line width of the metal mark portion may be substantially 0.1 μm or less. The metal material may be heavy metal material. In a preferred embodiment, the substrate has a plurality of the grooves; and the metal mark portion has the epitaxial metal membrane on a plurality of the side walls of the plurality of grooves.

According to a second aspect of the present invention, a target mark member for adjusting a focus of an electron beam and measuring a shape of the electron beam in an electron beam processing apparatus is provided. The target mark member comprises: a mark portion that has a first membrane formed by metal material and a second membrane formed by a material having an amount of emission of reflected electrons which is smaller than that of the metal material; said second membrane being formed on the first membrane and extending along a surface of the first membrane in a first direction; and a substrate to which said mark portion is attached at a surface substantially perpendicular to the first direction.

The material of the first membrane may be heavy metal material. Furthermore, the material of the second membrane may be silicon. Each of the first membrane and the second membrane may be epitaxial. A plurality of the first membranes and the second membranes may be laminated alternatively in the first direction. The distance between the first membranes that exist at each ends of the mark portion may be within a scanning width of the electron beam. Each line width of the plurality of first membranes may be substantially same. Each width of the plurality of second membranes may be substantially same. A longitudinal end of the first membrane may protrude from a longitudinal end surface of the second membrane. The second membrane may be integral with the substrate.

According to a third aspect of the present invention, an electron beam exposure apparatus for exposing a wafer by an electron beam is provided. The electron beam exposure apparatus comprises: an electron gun that generates said electron beam; an electron lens for adjusting a focus of said electron beam to a predetermined region of said wafer; and a wafer stage for installing said wafer; wherein: said wafer stage has a target mark member, which is used for adjusting a focus of said electron beam, that includes: a metal mark portion having a predetermined mark pattern, the metal mark portion comprising an epitaxial metal material; and a substrate for supporting said metal mark portion. The line width of said metal mark portion may be substantially 0.1 μm or less.

According to a fourth aspect of the present invention, an electron beam exposure apparatus for exposing a wafer by an electron beam is provided. The electron beam exposure apparatus comprises: an electron gun that generates said electron beam; an electron lens for adjusting a focus of said electron beam to a predetermined region of said wafer; and a wafer stage for installing said wafer; wherein: said wafer stage has a target mark member, which is used for adjusting a focus of said electron beam, that includes: a predetermined mark pattern that has a first membrane formed by metal material and a second membrane formed by a material having an amount of emission of reflected electrons which is smaller than that of said metal material; the second membrane being formed on the first membrane and extending along a surface of the first membrane in a first direction; and a substrate to which the first membrane and the second membrane are attached at a surface substantially perpendicular to the first direction.

According to a fifth aspect of the present invention, a method for manufacturing a target mark member that has a metal mark portion having a predetermined mark pattern, which is used for adjusting a focus of an electron beam and measuring a shape of the electron beam, in an electron beam processing apparatus is provided. The method comprises: a step of forming a plurality of grooves on a substrate; and a step of forming the metal mark portion by an epitaxial metal membrane on side walls of each of the grooves.

The step of forming the plurality of grooves may form the plurality of grooves on a substrate at a constant interval. The step of forming the metal mark portion may form the metal membranes for each of the plurality of side walls. The step of forming the metal mark portion may form each line width of the metal membranes to be substantially same. The distance between the metal membranes that exist at each ends of the metal mark portion may be formed within a scanning width of the electron beam. The step of forming the metal mark portion may form the metal membrane using heavy metal material.

According to a sixth aspect of the present invention, a method for manufacturing a target mark member that has a predetermined mark pattern used for adjusting a focus of an electron beam and measuring a shape of the electron beam in an electron beam processing apparatus is provided. The method comprises a step of forming a first membrane on a base to extend along a surface of the base in a first direction; a step of forming a second membrane on the first membrane to extend in the first direction; removing the base from the first membrane; and a step of attaching the first membrane and the second membrane to a substrate so that the first direction is substantially perpendicular to a surface of the substrate.

The step of forming the first membrane may form the first membrane by epitaxial growth; and the step of forming the second membrane may form the second membrane on the first membrane by epitaxial growth. The step of forming the first membrane may use heavy metal material as a material of the first membrane. The step of laminating the second membrane may form the second membrane using a material having an amount of emission of reflected electrons which is smaller than that of the first membrane. The step of laminating the second membrane may form the second membrane by silicon. The step of forming the first membrane and the step of forming the second membrane may be performed alternatively for a plurality of times to form a plurality of the first membranes and the second membranes.

The step of forming the first membrane may form the first membranes so that a distance between the first membranes that exist at each ends of the target mark member is within a scanning width of the electron beam. The step of forming the first membrane may form each line width of the plurality of the first membranes to be substantially same. The step of forming the second membrane may form each thickness of the plurality of the second membranes to be substantially same. The method may further comprise: etching the second membrane so that a longitudinal end of the first membrane protrudes from a longitudinal end surface of the second membrane.

The summary of the invention does not necessarily describe all necessary features of the present invention. The present invention may also be a sub-combination of the features described above. The above and other features and advantages of the present invention will become more apparent from the following description of the embodiments taken in conjunction with the accompanying drawings.

### BRIEF DESCRIPTION OF THE DRAWINGS

FIG. 1 shows an operation of measuring a shape of an electron beam and focusing an electron beam using a conventional target mark member 170.

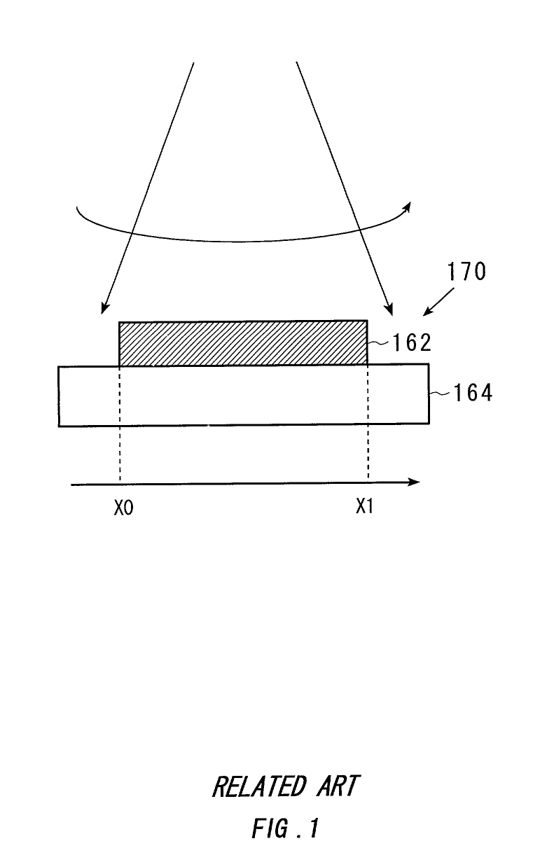

FIGS. 2(A-B) show an example of the measuring result of the amount of the reflected electrons, the focus of which is adjusted using the conventional target member 170 in FIG. 1.

FIG. 3 shows a configuration of an electron beam exposure apparatus 100 according to an embodiment of the present invention.

FIG. 4 shows a concept of measuring the shape of an electron beam and adjusting the focus using the target mark member 160 of an embodiment of the present invention.

FIGS. 5(A-B) show an example of the result that measures the amount of reflected electrons emitted from the metal mark portion 202 using the target mark member 160 of the present embodiment as shown in FIG. 4.

FIGS. 6(A-C) show a method of manufacturing the target mark member 160 of the present embodiment.

FIGS. 7((A-E) show another embodiment of a method of manufacturing the target mark member 160 that has a metal mark portion including a predetermined mark pattern.

FIG. 8 shows another embodiment of a method of manufacturing the target mark member 160.

### DETAILED DESCRIPTION OF THE INVENTION

The invention will now be described based on the preferred embodiments, which do not intend to limit the scope of the present invention, but exemplify the invention. All of the features and the combinations thereof described in the embodiment are not necessarily essential to the invention.

### Context of the Invention

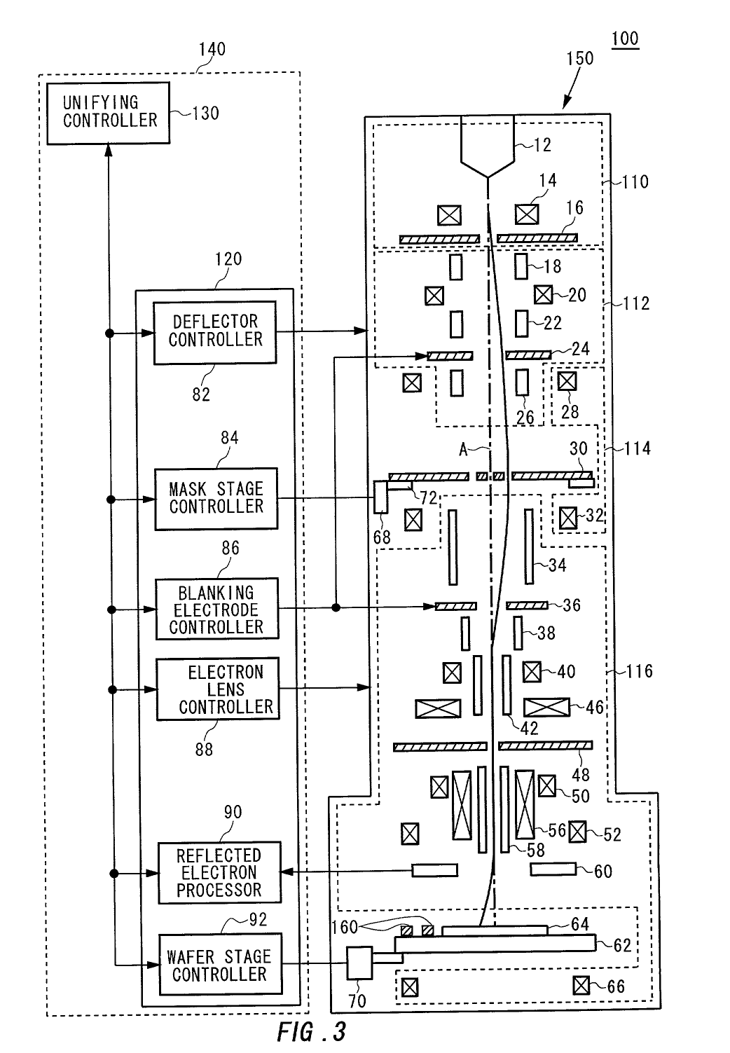

FIG. 3 shows a configuration of an electron beam exposure apparatus 100 according to an embodiment of the present invention. The electron beam exposure apparatus 100 comprises an exposing unit 150 that executes a predetermined exposure process on a wafer 64 using an electron beam, and a controller system 140 that controls the operation of each component of the exposing unit 150.

The exposing unit 150 has an electron beam irradiating system 110, a mask projection system 112, an adjusting lens system 114, and an electron optical system that includes a wafer projection system 116. The electron beam irradiating system 110 irradiates a predetermined electron beam. The mask projection system 112 deflects an electron beam, which is irradiated from an electron beam irradiating system 110, and also adjusts the imaging position of an electron beam at a periphery of a mask 30.

The focus adjusting lens system 114 images the crossover image of the electron beam at the periphery of the round aperture 48. The electron optical system includes a wafer projection system 116 that deflects an electron beam, which passes through the mask 30, to a predetermined region of the wafer 64 positioned on the wafer stage 62. The wafer projection system 116 also adjusts a direction and a size of the image of the pattern, which is to be transcribed to the wafer 64.

Furthermore, the exposing unit 150 comprises a stage system that includes a mask stage 72, a mask stage driving unit 68, a wafer stage 62, and a wafer stage driving unit 70. The mask 30 is positioned on the mask stage 72. The mask 30 has a plurality of blocks on which each of the patterns that are to be exposed to the wafer 64 are formed. The mask stage driving unit 68 drives the mask stage 72. The wafer 64, on which the pattern is exposed, is positioned on the wafer stage 62. The wafer stage-driving unit 70 drives the wafer stage 62.

Furthermore, the exposing unit 150 has an electron detector 60 that detects the electrons scattered from the wafer stage 62 side, and converts the detected electrons to an electric signal that corresponds to an amount of the scattered electrons, for adjusting the electron optical system. The wafer stage 62 has a target mark member 160 that is used for adjusting the focus, the amount of deflection, and/or the beam shape of the electron beam.

The electron beam irradiating system 110 has a first electron lens 14 and a slit 16. The first electron lens 14 determines the focus position of the crossover image of an electron beam, which is generated at the electron gun 12. A rectangular shaped slit for the electron beam to pass through is formed on the slit 16. Because the electron gun 12 needs a predetermined time to generate a stable electron beam, the electron gun 12 may continuously generate an electron beam during an exposing process period.

A slit is preferably formed in a shape, which matches the shape of the block that includes a predetermined pattern formed on the mask 30. In FIG. 3, the optical axis of the electron beam, when the electron beam irradiated from the electron beam irradiating system 110 is not deflected by the electron optical system, is expressed by the projected line A.

The mask projection system 112 has a first deflector 18, a second deflector 22, a third deflector 26, a second electron lens 20, and a first blanking electrode 24. The first deflector 18, the second deflector 22, and the third deflector 26 operate as a deflecting system for a mask that deflects an electron beam. The second electron lens 20 operates as a focusing system for a mask that adjusts the focus of the electron beam. The first deflector 18 and the second deflector 22 deflect the electron beam to irradiate the electron beam on the predetermined region of the mask 30.

For example, the predetermined region may be a block having a pattern to be transcribed into the wafer 64. The cross sectional shape of an electron beam becomes the same shape as the pattern because of the electron beam passing through the pattern. The image of the electron beam that passed through the block, on which a predetermined pattern is formed, is defined as a pattern image. The third deflector 26 deflects the orbit of the electron beam which passed through the first deflector 18 and the second deflector 22, to be approximately parallel to the optical axis A. The second electron lens 20 has a function for imaging the image of the opening of the slit 16 on the mask 30, which is provided on the mask stage 72.

The adjusting lens system 114 has a third electron lens 28 and a fourth electron lens 32. The third electron lens 28 and the fourth electron lens 32 focus the electron beam on the wafer 64. The wafer projection system 116 has a fifth electron lens 40, a sixth electron lens 46, a seventh electron lens 50, an eighth electron lens 52, a ninth electron lens 66, a fourth deflector 34, a fifth deflector 38, a sixth deflector 42, a main deflector 56, a sub deflector 58, a second blanking deflector 36, and a round aperture 48.

The pattern image rotates due to the influence of the set value of the intensity of the lenses. The fifth electron lens 40 adjusts the amount of rotation of the pattern image of the electron beam, which passed through the predetermined block of the mask 30. The sixth electron lens 46 and the seventh electron lens 50 adjust a reduction ratio of the image pattern, which is transcribed onto the wafer 64, against the pattern formed on the mask 30. The eighth electron lens 52 and the ninth electron lens 66 function as an object lens.

The fourth deflector 34 and the sixth deflector 42 deflect the electron beam to the direction of the optical axis A at the downstream of the mask 30 in the forward direction of the electron beam. The fifth deflector 38 deflects the electron beam such that the electron beam runs approximately parallel to the optical axis A. The main deflector 56 and the sub deflector 58 deflect the electron beam such that the electron beam irradiates at the predetermined region on the wafer 64. In the present embodiment, the main deflector 56 is used for deflecting the electron beam between the sub fields that include a plurality of shot regions, which are regions that can be irradiated with one shot of the electron beam. The sub deflector 58 is used for deflecting the electron beam between the shot regions on the sub field.

The round aperture 48 has a round aperture. The first blanking electrode 24 and the second blanking deflector 36 can switch on/off the electron beam by synchronizing the electron beam at high speed. Specifically, the first blanking electrode 24 and the second blanking deflector 36 have a function of deflecting the electron beam so that the electron beam irradiates the outside of the round aperture 48. That is, the first blanking electrode 24 and the second blanking deflector 36 can control the amount of the electron beam, which reaches on the wafer 64, without changing the pattern image that images on the wafer 64.

Therefore, the first blanking electrode 24 and the second blanking deflector 36 can prevent the electron beam from advancing past the round aperture 48, in the forward direction of the electron beam. Because the electron gun 12 always irradiates the electron beam during the exposing process period, the first blanking electrode 24 and the second blanking deflector 36 preferably deflect the electron beam such that the electron beam does not advance past the round aperture 48, when changing the pattern which is to be transcribed into the wafer 64, or when changing the region of the wafer 64 on which the pattern is to be exposed.

The controller system 140 comprises a unifying controller 130 and an individual controller 120. The individual controller 120 has a deflector controller 82, a mask stage controller 84, a shot controller 86, an electron lens controller 88, a reflected electron processor 90, and a wafer stage controller 92. The unifying controller 130 is, for example, a workstation that unifies and controls each of the controlling units, which are included in the individual controller 120. The deflector controller 82 controls the first deflector 18, the second deflector 22, the third deflector 26, the fourth deflector 34, the fifth deflector 38, the sixth deflector 42, the main deflector 56, and the sub deflector 58. The mask stage controller 84 controls the mask stage-driving unit 68 to move the mask stage 72.

The shot controller 86 controls the first blanking electrode 24 and the second blanking deflector 36. In the present embodiment, the first blanking electrode 24 and the second blanking deflector 36 are preferably to be controlled such that the electron beam is irradiated on the wafer 64 during the exposing process, and the electron beam does not reach the wafer 64 except during the exposing process.

The electron lens controller 88 controls the electric current, which is to be provided to the first electron lens 14, the second electron lens 20, the third electron lens 28, the fourth electron lens 32, the fifth electron lens 40, the sixth electron lens 46, the seventh electron lens 50, the eighth electron lens 52, and the ninth electron lens 66. The reflected electron processor 90 detects the digital data, which shows an electron quantity based on the electric signal detected by the electron detector 60. The wafer stage controller 92 moves the wafer stage 62 to a predetermined position using the wafer stage-driving unit 70.

An operation of the electron beam exposure apparatus 100 according to the present embodiment will be explained. The electron beam exposure apparatus 100 performs an adjustment process, which adjusts the configuration, such as the electron optical system, in advance before performing the exposing process.

In the following, first, the adjustment process of the electron optical system before the exposing process will be explained. The wafer stage 62 has a target mark member 160 that is used for adjusting the focus and the degree of deflection of the electron beam and/or measuring the size of the electron beam. The target mark member 160 is preferably provided on the wafer stage 62 except the region where the wafer is placed.

To focus the electron beam, the wafer stage controller 92 moves the target mark member 160, which is provided on the wafer stage 62 for focus adjustment, to the periphery of the optical axis A, using the wafer stage driving unit 70. In the present embodiment, the target mark member 160 comprises a metal mark portion that has a minute mark pattern made by growing the metal material epitaxially. Next, the focus position of each of the lenses is adjusted to the predetermined position. Then, the electron beam scans the metal mark portion of the target mark member 160. At the same time, the electron detector 60 outputs the electric signal according to the reflected electrons generated by irradiating the electron beam on the target mark member 160.

The reflected electron processor 90 detects the amount of reflected electrons and notifies the amount of detected electrons to the unifying controller 130. The unifying controller 130 judges whether the lens system is focused or not based on the detected electron quantity. The unifying controller 130 controls the electric current, which is provided to each of the electron lens, in order to maximize the differential value of the detected waveform of the reflected electrons.

Furthermore, the wafer stage controller 92 moves the target mark member 160, which is provided on the wafer stage 62 for measuring the beam shape, to the periphery of the optical axis A using the wafer stage driving unit 70. In the present embodiment, the target mark member 160 used for measuring the beam shape may be same as the target mark member 160 used for focusing. The level of the upper surface of the metal mark portion is preferably on the same level as the surface of the wafer 64. If the metal mark portion is scanned by the electron beam in two dimensions, the electron beam, which is proportional to the distribution of the beam, is reflected from the metal mark portion. By recording the reflected electron signal while synchronizing the reflected electron signal with the beam scanning signal of the deflection circuit, a two dimensional distribution of the beam corresponding to the deflection position is obtained, and therefore the beam shape is measured.

For example, when the coordinate system of the electron beam exposure apparatus 100 is configured using such as a laser interferometer as a reference to perform the exposing process in high accuracy, it is necessary to correct the deflection coordinate system of the electron beam and the orthogonal coordinate system, which refers to the laser interferometer, accurately. Therefore, after the electron beam is focused, the wafer stage controller 92 moves the target mark member 160, which is provided on the wafer stage 62 and on which the predetermined marking is formed for correcting the amount of the deflection, to the periphery of the optical axis A using the wafer stage driving unit 70 to correct the amount of deflection.

The deflector deflects the electron beam to scan for a plurality of times the electron beam on the marking of the target mark member 160, which is used for adjusting the amount of deflection. The electron detector 60 detects the change of the reflected electrons, which is emitted from the target mark member 160, and notifies the change to the unifying controller 130. The unifying controller 130 can determine the edge of the mark and find the central position of the mark coordinate based on the detected waveform of the reflected electrons. By detecting the marking as shown above, the deflection coordinate system and the orthogonal coordinate system can be corrected. Also, the deflector can accurately irradiate the electron beam to the predetermined region of the wafer.

Next, operations of each of components of the electron beam exposure apparatus 100 during execution of the exposing process will be explained. The mask 30, which has a plurality of blocks on which a predetermined pattern is formed, is provided on the mask stage 72, and the mask 30 is fixed to the predetermined position. Furthermore, the wafer 64, on which an exposing process is performed, is provided on the wafer stage 62.

The wafer stage controller 92 moves the wafer stage 62 by the wafer stage driving unit 70, to locate the region of the wafer 64 which is to be exposed, at the periphery of the optical axis A. Moreover, because the electron gun 12 always irradiates the electron beam during the exposing process period, the shot controller 86 controls the first blanking electrode 24 and the second blanking deflector 36 so that the electron beam, which passed through the opening of the slit 16, does not become irradiated to the wafer 64 before the start of the exposing process.

In the mask projection system 112, the second electron lens 20 and the deflectors 18, 22, and 26 are adjusted so that the electron beam can be irradiated on the block on which the pattern to be transcribed to the wafer 64 is formed. In the adjusting lens system 114, the electron lenses 28 and 32 are adjusted so that the crossover position of the electron beam is focused to the round aperture 48. Moreover, in the wafer projection system 116, the electron lenses 40, 46, 50, 52, and 66, and the deflectors 34, 38, 42, 56, and 58 are adjusted so that the pattern image can be transcribed to the predetermined region of the wafer 64.

After adjusting the mask projection system 112, the adjusting lens system 114, and the wafer projection system 116, the shot controller 86 stops the deflection of the electron beam of the first blanking electrode 24 and the second blanking deflector 36. Thereby, the electron beam is irradiated to the wafer 64 through the mask 30. The electron gun 12 generates an electron beam, and the first electron lens 14 adjusts the focus position of the electron beam to irradiate the electron beam to the slit 16. Then, the first deflector 18 and the second deflector 22 deflect the electron beam, which passed through the opening of the slit 16, to irradiate the electron beam to the predetermined region of the mask 30, on which the pattern to be transcribed is formed.

The electron beam, which passed through the opening of the slit 16, has a rectangular cross section. The electron beam, which is deflected by the first deflector 18 and the second deflector 22, is deflected to be approximately parallel to the optical axis A by the third deflector 26. Moreover, the electron beam is adjusted so that the image of the opening of the slit 16 is imaged at the predetermined region on the mask 30 by the second electron lens 20.

Then, the electron beam that passed through the pattern, which is formed on the mask 30, is deflected to the direction close to the optical axis A by the fourth deflector 34 and the sixth deflector 42, and the electron beam is deflected to be approximately parallel to the optical axis A by the fifth deflector 38. Moreover, the electron beam is adjusted so that the image of the pattern, which is formed on the mask 30, is focused on the surface of the wafer 64 by the third electron lens 28 and the fourth electron lens 32. The rotation amount of the pattern image is adjusted by the fifth electron lens 40, and the ratio of reduction of the pattern image is adjusted by the sixth electron lens 46 and the seventh electron lens 50.

Then, the electron beam is deflected so that the electron beam is irradiated to the predetermined shot region on the wafer 64 by the main deflector 56 and the sub deflector 58. In the present embodiment, the main deflector 56 deflects the electron beam between the sub fields that include a plurality of shot regions. The sub deflector 58 deflects the electron beam between the shot regions in the sub field. The electron beam deflected to the predetermined shot region is adjusted by the eighth electron lens 52 and the ninth electron lens 66 and is irradiated to the wafer 64. Thereby, the pattern image formed on the mask 30 is transcribed onto the predetermined shot region on the wafer 64.

After the predetermined exposure period has elapsed, the shot controller 86 controls the first blanking electrode 24 and the second blanking deflector 36 to deflect the electron beam so as not to irradiate the electron beam on the wafer 64. The above-mentioned process exposes the pattern, which is formed on the mask 30, on the predetermined shot region on the wafer 64.

To expose the pattern, which is formed on the mask 30, to the next shot region, in the mask projection system 112, the second electron lens 20 and the deflectors 18, 22, and 26 are adjusted so that the electron beam can be irradiated on the block on which the pattern to be transcribed to the wafer 64 is formed. In the adjusting lens system 114, the electron lenses 28 and 32 are adjusted so that the crossover position of the electron beam is focused to the round aperture 48. Moreover, in the wafer projection system 116, the electron lenses 40, 46, 50, 52, and 66, and the deflectors 34, 38, 42, 56, and 58 are adjusted so that the pattern image can be transcribed to the predetermined region of the wafer 64.

Specifically, the sub deflector 58 adjusts the electric field so that the pattern image generated by the mask projection system 112 is exposed to the next shot region. Then, the pattern is exposed to the shot region as shown above. After exposing the pattern to the entire shot region, which is required to be exposed, inside the sub field, the main deflector 56 adjusts the magnetic field so that the pattern can be exposed to the next sub field. The electron beam exposure apparatus 100 can expose the desired circuit pattern on the wafer 64 by repeatedly performing the above-mentioned exposing process.

### Target Mark Member, Method for Manufacturing and Electron Beam Exposure Apparatus Thereof

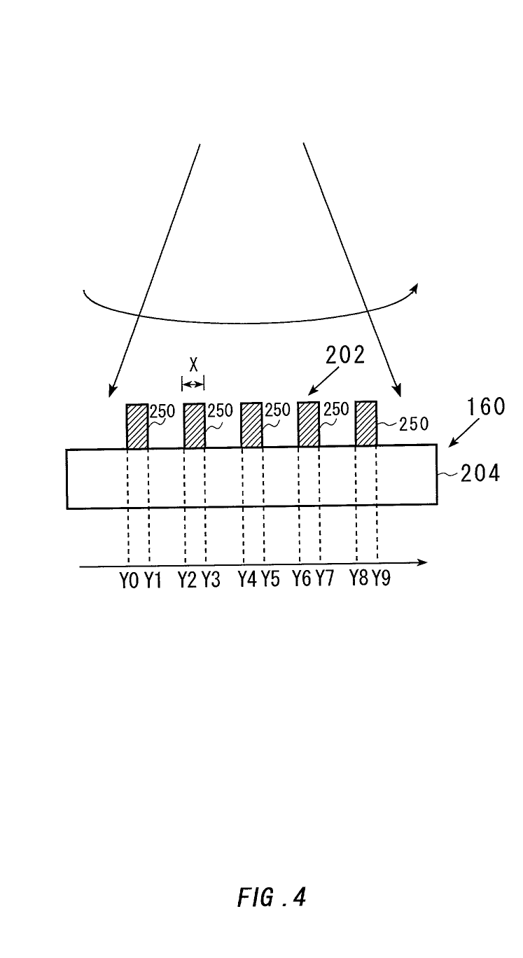

FIG. 4 shows a concept of measuring the shape of an electron beam and adjusting the focus using the target mark member 160 of an embodiment of the present invention. The target mark member 160 of the present embodiment is preferably used for measuring the shape of the electron beam and adjusting the focus of the electron beam in an electron beam processing apparatus such as the electron beam exposure apparatus 100. The target mark member 160 comprises a metal mark portion 202 and a substrate 204. The metal mark portion 202 has a predetermined mark pattern including a plurality of line marks 250 formed by growing a metal material epitaxially. The substrate 204 supports the metal mark portion 202. Especially, in case of using the target mark member 160 for measuring the shape of the electron beam and adjusting the focus of the electron beam, the metal mark portion 202 is preferably formed using a heavy metal material such as tungsten (W) that emits large amount of reflected electrons of the electron beam.

Because the metal mark portion 202 according to the present embodiment is formed by growing the metal material epitaxially, the line width X (note FIG. 4) of the line marks 250 of the metal mark portion 202 can be configured narrower than the line width X of the metal mark portion 162 in the conventional target mark material 170. Furthermore, the line width X of the line marks 250 of the metal mark portion 202 can be controlled in the order of the atomic layer using the epitaxial growth technology. The line width X of the line marks 250 of the metal mark portion 202 is preferably formed to be about 0.15 μm or smaller. More preferably, the line width X of the line marks 250 of the metal mark portion 202 is formed to be about 0.1 μm or smaller. More preferably, the line width X of the line marks 250 of the metal mark portion 202 is formed to be about 0.01 μm or smaller. The shape of the electron beam can be accurately measured by forming the line width X of the line marks 250 of the metal mark portion 202 smaller than the shape of the electron beam.

According to the present embodiment, the line marks 250 of the metal mark portion 202 can be provided on the substrate 204 within the scanning width of the electron beam. Furthermore, because the metal mark portion 202 has crystallinity, the metal mark portion 202 has a lower resistance than the resistance of the conventional metal mark portion 162. Thus, the metal mark portion 202 is difficult to be charged compared to the metal mark portion 162 even if the electron beam irradiates the metal mark portion 202.

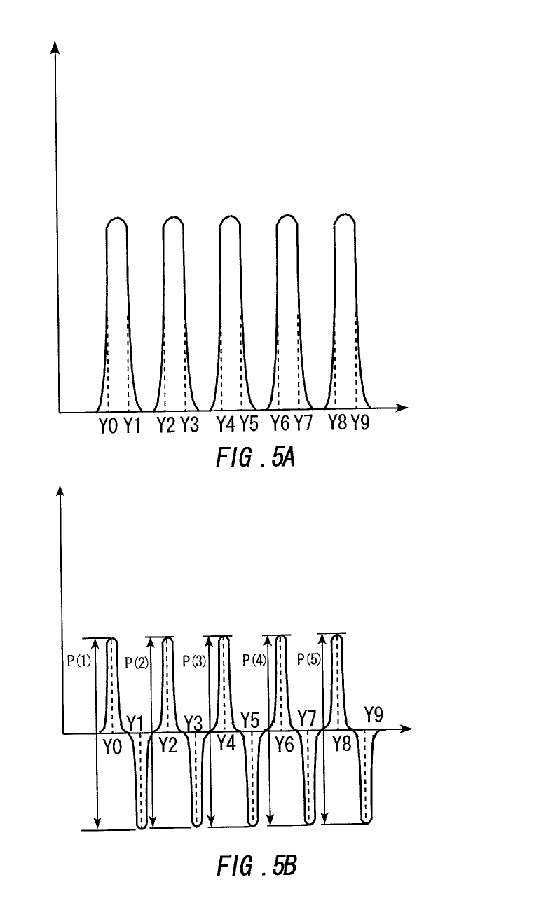

FIGS. 5A-B show an example of the result that measures the amount of reflected electrons emitted from the metal mark portion 202 using the target mark member 160 of the present embodiment as shown in FIG. 4. FIG. 5A shows the profile of the measured amount of the emitted electrons. At the periphery of the center of each line marks 250 (Y0-Y9) of the metal mark portion 202, the amount of the emitted electrons becomes approximately the maximum value. FIG. 5B shows the result that differentiates the profile of the measured amount of the emitted electrons of FIG. 5A. At the periphery of the edge (Y0-Y9) of the line marks 250 of the metal mark portion 202, the inclination of the curve of FIG. 5A becomes the maximum value or the minimum value. The difference between the maximum value and the minimum value of the inclination is shown as P(n) in FIG. 5B. As shown in FIG. 5B, five difference values from P(1) to P(5) can be obtained using the target mark member 160 of the present embodiment.

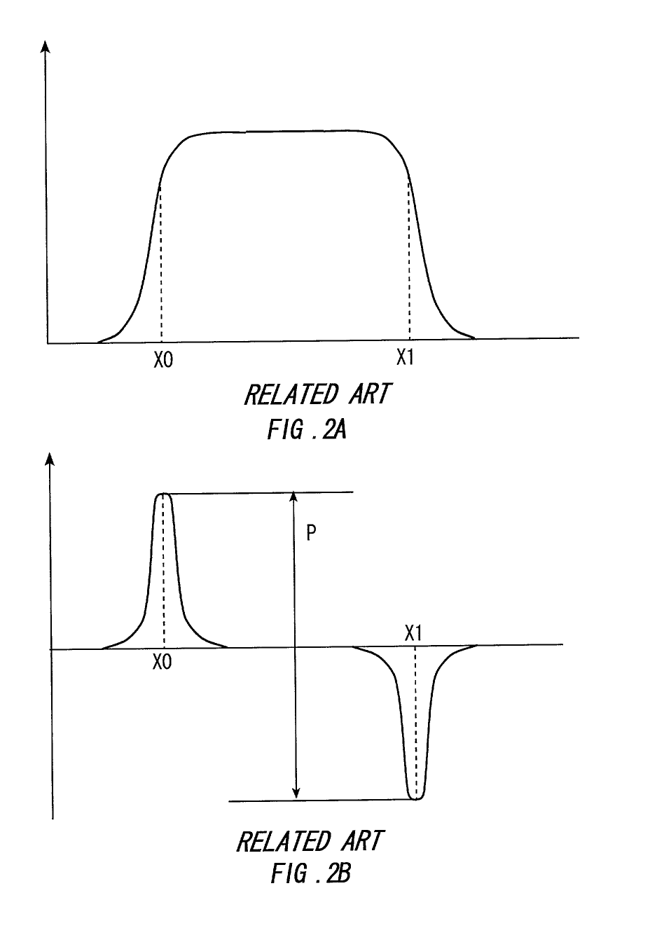

As shown in FIG. 2, in case of adjusting the focus using the conventional target mark member 170, only one difference value P is obtained by the one time of beam scanning. Therefore, conventionally, the focus is adjusted by scanning the target mark material a plurality of times by the electron beam and calculating the average value of the obtained difference values P. However, if the focus is adjusted using the target mark member 160 of the present embodiment, a plurality of difference values P(1)-P(5) can be obtained by one time of the beam scanning. Thus, the focus can be adjusted by calculating the average value of the difference values of P(1)-P(5), and therefore the time of the beam scanning required for the focus adjustment can be reduced. As a result, the time taken for the focus adjustment can be reduced.

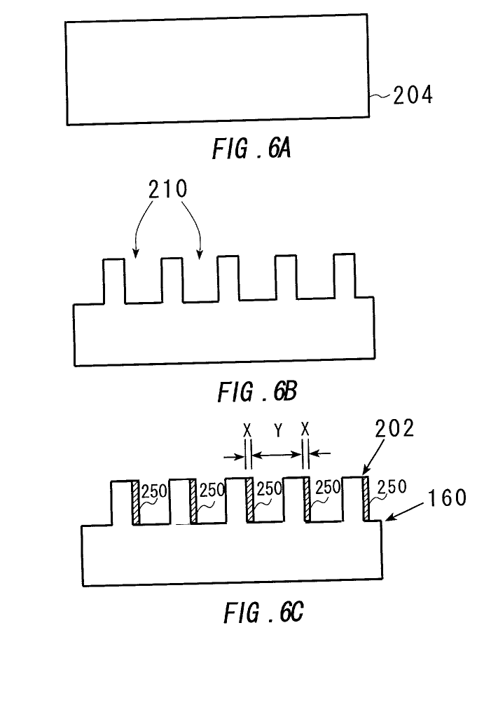

FIG. 6 shows a method of manufacturing the target mark member 160 of the present embodiment. The target mark member 160 has a metal mark portion 202, which has a predetermined mark pattern. The target mark member 160 is provided in the electron beam processing apparatus such as the electron beam exposure apparatus 100. The predetermined mark pattern of the metal mark portion 202 is used for adjusting the focus of the electron beam and measuring the shape of the electron beam.

First, as shown in FIG. 6A, the substrate 204 is prepared. For example, the substrate 204 may be made from silicon (Si). Then, a photo resist is applied on the substrate 204. The predetermined region of the substrate 204 is exposed, developed, and etched based on the predetermined mark pattern of the metal mark portion 202. As a result, as shown in FIG. 6B, a plurality of grooves 210 are formed on the substrate 204. The grooves 210 are preferably formed at a constant interval in the substrate 204.

Then, as shown in FIG. 6C, metal material is epitaxially grown on each side walls of the grooves 210, and the metal mark portions 202 can thus be formed. The metal material is preferably heavy metal material that emits a large amount of the reflected electrons of the electron beam, such as tungsten, and also preferably metal material that can be grown in the selected region of the substrate 204. For example, it is preferable to grow the metal membrane only on the selected region of the groove 210 such as the side wall of the groove 210 by covering the bottom part of the groove 210 by a material such as SiO₂ that does not grow the metal material.

Because the present embodiment forms the metal mark portion 202 by growing the metal material epitaxially, the line width X (note FIG. 6C), of the metal mark portion 202 can be controlled to the desired thickness. When the target mark member 160 is used for adjusting the focus of the electron beam, the line marks 250 of the metal mark portion 202 is preferably formed such that each of the line marks 250 have a same line width X from the corresponding side walls, and also each of the line marks 250 are arranged at a constant interval Y (note FIG. 6C).

In this example, the metal mark portion 202 is formed only on one of the side walls of the groove 210, however, the metal mark portion 202 can be formed on both sides of the side walls of the groove 210 as another example. Also in this another example, the line mark of the metal mark portion 202 is preferably formed such that each of the line marks 250 have a same width from the corresponding side walls, and also each of the line marks 250 are arranged at a constant interval.

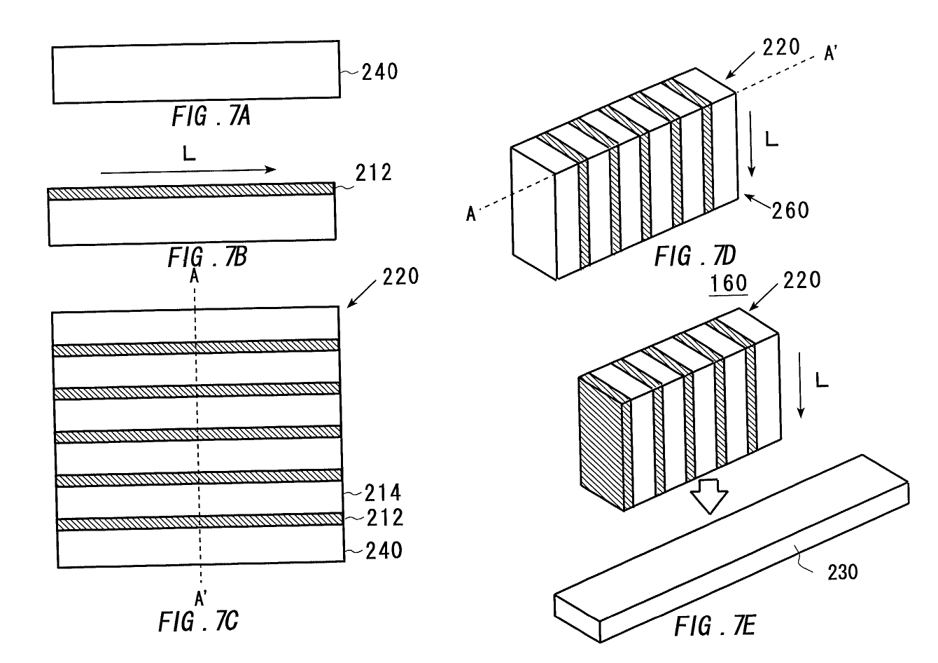

FIG. 7 shows another embodiment of a method of manufacturing the target mark member 160 that has a metal mark portion including a predetermined mark pattern. The target mark member 160 is provided in the electron beam processing apparatus. The predetermined mark pattern of the metal mark portion is used for adjusting the focus of the electron beam and measuring the shape of the electron beam.

First, as shown in FIG. 7A, the base 240 made from such as silicon is prepared. Then, as shown in FIG. 7B, a first membrane 212 is formed on the base 240 to extend along the surface of the base 204 in a first direction L using a first material. Here, the first material is preferably a metal material that emits a large amount of reflected electrons of an electron beam. The first material is further preferably a heavy metal material such as tungsten.

Next, a second membrane 214 is formed on the first membrane 212 by a second material in the first direction L. The second material is preferably a material that emits a small amount of the reflected electrons than the first material. For example, the second material may be a same material as the base 240, such as silicon.

A membrane-grown substrate 220 is generated by laminating the first membrane 212 and the second membrane 214, alternatively, in the first direction L for a plurality of times. The present embodiment alternatively laminates the first membrane 212 and the second membrane 214 in the first direction L for five times. The number of times of the lamination is preferably determined such that the distance between the lowest layer of the first membrane 212 and the highest layer of the first membrane 212 is within the scanning width of the electron beam of the electron beam exposure apparatus 100.

Furthermore, each thickness of the first membranes 212 is preferably formed to be the same thickness. Similarly, the thickness of each of the second membranes 214 is preferably formed to be the same thickness. The plurality of first membranes 212 can be formed at constant interval by controlling each thickness of the first membranes 212 to be the same and also controlling each thickness of the second membranes 214 to be the same.

In another embodiment, each of the first membranes 212 may be formed at a different interval. Furthermore, the thickness of the first membrane 212 and the second membrane 214 are preferably formed to be as thin as possible so that as many as possible line marks 250 can exist within the scanning width of the electron beam when the target mark member 160 is installed in the electron beam exposure apparatus 100.

Next, the metal mark portion 202 is formed by splitting or cutting the membrane-grown substrate 220 as shown in FIG. 7C along the line A-A′ of FIG. 7C. In the present embodiment, the end surface of a plurality of the first membranes 212, which are exposed on the splitting face 260 (note FIG. 7D) of the membrane-grown substrate 220, are used as a metal mark portion 202 having a predetermined mark pattern.

Then, the base 240 is removed from the membrane-grown substrate 220. Next, the membrane-grown substrate 220, from which the base 240 is removed, is attached to the substrate 230 such that the first direction L is in a direction substantially perpendicular to a surface of the substrate 230 as shown in FIG. 7E. Then, the target mark member 160 is formed. The substrate 230 may be formed by the same material as the base 240, such as silicon.

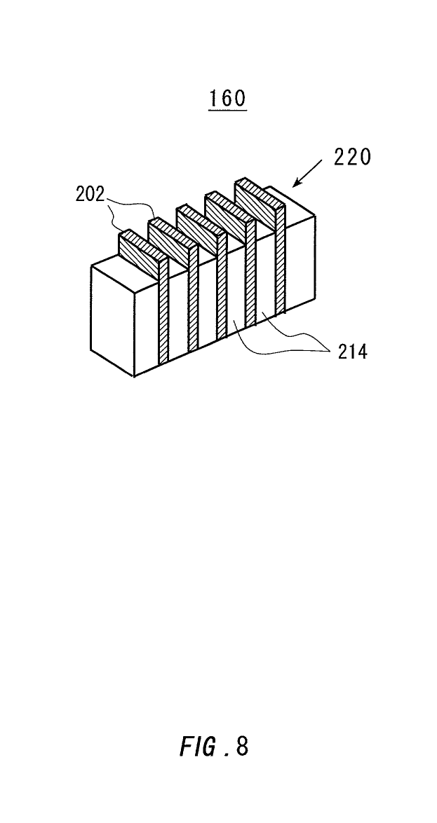

Furthermore, as shown in FIG. 8, it is preferable to etch ends of the second membranes 214 so that the upper or longitudinal ends of the metal mark portions 202 protrude from the upper or longitudinal end surfaces of the second membranes 214.

In FIGS. 7A-7E and FIG. 8, an example is taken for using an epitaxial growth for forming the first membrane 212 and the second membrane 214. However, the method of forming the first membrane 212 and the second membrane 214 is not limited to epitaxial growth. Any other method which provides the same advantageous results as described herein may be used for forming the first membrane 212 and second membrane 214 as shown in FIGS. 7A-7E.

Furthermore, plating may be used for manufacturing the target mark member 160 that comprises a metal mark portion having a predetermined mark pattern as another embodiment. For example, a substrate formed by such as silicon is prepared. Next, plurality of holes that pass through the substrate are formed in the substrate at constant interval. Then, an electrode plate is provided on the bottom of the substrate, and a voltage is applied on the electrode plate. Then, each of the holes of the substrate is plated with metal from bottom to top to form the metal mark portion. As a further embodiment, a conductive substrate may be provided on the bottom of the substrate instead of the electrode plate.

As shown above, the target mark member 160 according to the present embodiment is explained in relation to the electron beam exposure apparatus 100. As another embodiment, the target mark member 160 can be used for the electron beam processing apparatus such as an electron microscope, an electron beam testing apparatus, and an electron beam length measurement apparatus. As clear from the above explanation, the present invention can provide the target mark member having a minute or small line width X.

Although the present invention has been described by way of exemplary embodiments, it should be understood that those skilled in the art might make many changes and substitutions without departing from the spirit and the scope of the present invention which is defined only by the appended claims.

What is claimed is:

1. A target mark member for adjusting a focus of an electron beam and measuring a shape of said electron beam in an electron beam processing apparatus, comprising:
a metal mark portion having a predetermined mark pattern, said metal mark portion comprising an epitaxial metal material; and
a substrate that supports said metal mark portion.

2. A target mark member as claimed in claim 1, wherein:
said substrate has a groove that has side walls; and
said metal mark portion has an epitaxial metal membrane on at least one of said side walls of said groove.

3. A target mark member as claimed in claim 1 or 2, wherein a line width of said metal mark portion is substantially 0.1 μm or less.

4. A target mark member as claimed in claim 1, wherein said metal material is heavy metal material.

5. A target mark member as claimed in claim 2, wherein:
said substrate has a plurality of said grooves; and
said metal mark portion has said epitaxial metal membrane on a plurality of said side walls of said plurality of grooves.

6. A target mark member for adjusting a focus of an electron beam and measuring a shape of said electron beam in an electron beam processing apparatus, comprising:
a mark portion that has a first membrane formed by metal material and a second membrane formed by a material having an amount of emission of reflected electrons which is smaller than that of said metal material; said second membrane being formed on said first membrane and extending along a surface of said first membrane in a first direction; and
a substrate to which said mark portion is attached at a surface substantially perpendicular to said first direction.

7. A target mark member as claimed in claim 6, wherein a material of said first membrane is heavy metal material.

8. A target mark member as claimed in claim 6, wherein a material of said second membrane is silicon.

9. A target mark member as claimed in claim 6, wherein each of said first membrane and said second membrane are epitaxial.

10. A target mark member as claimed in claim 6, wherein a plurality of said first membranes and said second membranes are laminated alternatively in said first direction.

11. A target mark member as claimed in claim 10, wherein a distance between said first membranes that exist at each ends of said mark portion is within a scanning width of said electron beam.

12. A target mark member as claimed in claim 10, wherein each line width of said plurality of first membranes is substantially same.

13. A target mark member as claimed in claim 10, wherein each width of said plurality of second membranes is substantially same.

14. A target mark member as claimed in claim 6, wherein a longitudinal end of said first membrane protrudes from a longitudinal end surface of said second membrane.

15. A target mark member as claimed in claim 6, wherein said second membrane is integral with said substrate.

16. An electron beam exposure apparatus for exposing a wafer by an electron beam, comprising:
an electron gun that generates said electron beam;
an electron lens for adjusting a focus of said electron beam to a predetermined region of said wafer; and
a wafer stage for installing said wafer; wherein:
said wafer stage has a target mark member, which is used for adjusting a focus of said electron beam, that includes:
a metal mark portion having a predetermined mark pattern, said metal mark portion comprising an epitaxial metal material; and
a substrate for supporting said metal mark portion.

17. An electron beam exposure apparatus as claimed in claim 16, wherein a line width of said metal mark portion is substantially 0.1 μm or less.

18. An electron beam exposure apparatus for exposing a wafer by an electron beam, comprising:
an electron gun that generates said electron beam;
an electron lens for adjusting a focus of said electron beam to a predetermined region of said wafer; and
a wafer stage for installing said wafer; wherein:
said wafer stage has a target mark member, which is used for adjusting a focus of said electron beam, that includes:
a predetermined mark pattern that has a first membrane formed by metal material and a second membrane formed by a material having an amount of emission of reflected electrons which is smaller than that of said metal material; said second membrane being formed on said first membrane and extending along a surface of said first membrane in a first direction; and
a substrate to which said first membrane and said second membrane are attached at a surface substantially perpendicular to said first direction.

19. A method for manufacturing a target mark member that has a metal mark portion having a predetermined mark pattern, which is used for adjusting a focus of an electron beam and measuring a shape of said electron beam, in an electron beam processing apparatus, comprising:
forming a plurality of grooves on a substrate; and
forming said metal mark portion by an epitaxial metal membrane on side walls of each of said grooves.

20. A method as claimed in claim 19, wherein said forming said plurality of grooves forms said plurality of grooves on a substrate at a constant interval.

21. A method as claimed in claim 19, wherein said forming said metal mark portion forms said metal membranes for each of said plurality of side walls.

22. A method as claimed in claim 21, wherein said forming said metal mark portion forms each line width of said metal membranes to be substantially same.

23. A method as claimed in claim 21, wherein a distance between said metal membranes that exist at each ends of said metal mark portion is formed within a scanning width of said electron beam.

24. A method as claimed in claim 19, wherein said forming said metal mark portion forms said metal membrane using heavy metal material.

25. A method for manufacturing a target mark member that has a predetermined mark pattern used for adjusting a focus of an electron beam and measuring a shape of said electron beam in an electron beam processing apparatus, comprising:
forming a first membrane on a base to extend along a surface of said base in a first direction;
forming a second membrane on said first membrane to extend in said first direction;
removing said base from said first membrane;
attaching said first membrane and said second membrane to a substrate so that said first direction is substantially perpendicular to a surface of said substrate.

26. A method as claimed in claim 25, wherein:
said forming said first membrane forms said first membrane by epitaxial growth; and
said forming said second membrane forms said second membrane on said first membrane by epitaxial growth.

27. A method as claimed in claim 25, wherein said forming said first membrane uses heavy metal material as a material of said first membrane.

28. A method as claimed in claim 25, wherein said forming said second membrane forms said second membrane using a material having an amount of emission of reflected electrons which is smaller than that of said first membrane.

29. A method as claimed in claim 31, wherein said forming said second membrane forms said second membrane by silicon.

30. A method as claimed in claim 25, wherein said forming said first membrane and said forming said second membrane are performed alternatively for a plurality of times to form a plurality of said first membranes and said second membranes.

31. A method as claimed in claim 30, wherein said forming said first membrane forms said first membranes so that a distance between said first membranes that exist closest to each ends of said target mark member is within a scanning width of said electron beam.

32. A method as claimed in claim 30, wherein said forming said first membrane forms each line width of said plurality of said first membranes to be substantially same.

33. A method as claimed in claim 30, wherein said forming said second membrane forms each thick ness of said plurality of said second membranes to be substantially same.

34. A method as claimed in claim 25, further comprising: etching said second membrane so that a longitudinal end of said first membrane protrudes from a longitudinal end surface of said second membrane.
